(19) United States
(12) Patent Application Publication
(10) Pub. No.: US 2025/0143003 A1
(43) Pub. Date: May 1, 2025

(54) METHOD FOR PREPARING TOPCon BATTERY SUBSTRATE AND DOUBLE-SIDED ELECTROPLATED TOPCon BATTERY PREPARED THEREFROM

(71) Applicant: HUANSHENG PHOTOVOLTAIC (JIANGSU) CO., LTD, Wuxi (CN)

(72) Inventors: Yiwu TANG, Wuxi (CN); Suqiang LI, Wuxi (CN); Kewei LI, Wuxi (CN); Tongzhou GUAN, Wuxi (CN); Chao YU, Wuxi (CN); Nan SONG, Wuxi (CN); Peng WANG, Wuxi (CN); Yan WANG, Wuxi (CN)

(73) Assignee: HUANSHENG PHOTOVOLTAIC (JIANGSU) CO., LTD, Wuxi (CN)

(21) Appl. No.: 19/002,794

(22) Filed: Dec. 27, 2024

Related U.S. Application Data
(63) Continuation of application No. PCT/CN2024/109546, filed on Aug. 2, 2024.

(30) Foreign Application Priority Data
Oct. 25, 2023 (CN) 202311394254.1

(51) Int. Cl. H10F 71/00; H10F 10/142; H10F 71/10

(52) U.S. Cl. CPC H10F 71/128; H10F 10/142; H10F 71/1035; H10F 71/134

(57) ABSTRACT

A method for preparing TOPCon battery substrate and double-sided electroplated TOPcon battery prepared therefrom are provided. The method includes: providing a double-sided grooved silicon matrix of a TOPCon battery; carrying out thermal repair treatment on the silicon matrix; respectively carrying out light injection treatment on the front side and the back side of the silicon matrix after thermal repair treatment, thereby the TOPCon battery substrate is obtained. Thermal repair treatment can greatly increase the overall lattice thermal motion of the silicon substrate, and light is injected into the front side and the back side in the directions of two different light incidence surfaces, so that both the front side and the back side can absorb light, thereby repairing the defects at the interface between the amorphous silicon and the silicon wafer and improving the quality of the PN junctions.

### CROSS REFERENCE TO THE RELATED APPLICATIONS

This application is a continuation application of International Application No. PCT/CN2024/109546, filed on Aug. 2, 2024, which is based upon and claims priority to Chinese Patent Application No. 202311394254.1, filed on Oct. 25, 2023, the entire contents of which are incorporated herein by reference.

### TECHNICAL FIELD

The present disclosure relates to the technical field of TOPCon solar cells, in particular to a method for preparing TOPCon battery substrate and double-sided electroplated TOPcon battery prepared therefrom.

### BACKGROUND

At present, in terms of the technical level of TOPCon solar cells, the cost of silver paste used in the traditional screen printing process is high, and it is difficult to effectively improve the height-width ratio of the prepared front finger. Compared with this technology, TOPCon battery prepared by horizontal double-sided electroplating has the following advantages: increasing the height-width ratio of the front finger; and reducing the width of the finger and increasing the light exposed area of the battery. Moreover, double-sided electrodes mainly rely on copper to conduct electricity, which is cheap and achieves the purpose of reducing the production cost of batteries.

However, the traditional grooving method of double-sided electroplated TOPCon battery is to directly groove silicon nitride by using a laser to expose the underneath silicon, thus ensuring that the electroplating process can be carried out, wherein the preparation process is: laser grooving on the front side→laser grooving on the back side→electroplating. In this grooving process, since the back side is a smooth polished surface, laser grooving causes little damage to the silicon substrate. However, the front side is a texturing surface with pyramid structure, if the silicon nitride film on the surface is removed by laser, it will inevitably cause some damage to the silicon substrate, which may destroy the PN junctions on the silicon substrate, resulting in the loss of the open circuit voltage of the battery sheet, thus leading to the reduction of the conversion efficiency of the final electroplated battery. Generally, the open circuit voltage loss caused by laser damage of double-sided electroplated TOPCon cells is about 10-20 mV, reflected in the efficiency of solar cells, and the efficiency loss is about 1-1.5%.

Therefore, it is urgent to develop a method to minimize the open circuit voltage loss caused by laser damage of double-sided electroplated TOPCon battery.

### SUMMARY

The present disclosure provides a method for preparing TOPcon battery substrate and double-sided electroplated TOPcon battery prepared therefrom, so as to at least solve one technical problem existing in the prior art.

In order to achieve at least one of the above objectives of the present disclosure, the following technical solution is adopted.

In the first aspect, the present disclosure provides a method for preparing a TOPCon battery substrate, which includes the following steps:
providing a double-sided grooved silicon matrix of a TOPCon battery;
applying thermal repair treatment to the silicon matrix;
performing light injection treatment on the front side and the back side of the silicon matrix after the thermal repair treatment, respectively, thereby obtaining a TOPCon battery substrate.

In a second aspect, the present disclosure provides a TOPCon battery substrate, wherein the TOPCon battery substrate is rendered by using the method as described above.

In a third aspect, the present disclosure provides a double-sided electroplated TOPCon battery, wherein the double-sided electroplated TOPCon battery is rendered by performing double-sided electroplating treatment on the TOPCon battery substrate as described above.

### DETAILED DESCRIPTION OF THE EMBODIMENTS

Embodiments of the present disclosure will be described in detail below with reference to examples, but those skilled in the art will understand that the following examples are only used to illustrate the present disclosure and should not be regarded as limiting the scope of the present disclosure. Where specific conditions are not specified in the examples, it shall be carried out according to the conventional conditions or the conditions suggested by the manufacturer.

In a first aspect, the present disclosure provides a method for preparing a TOPCon battery substrate and a double-sided electroplated TOPCon battery prepared therefrom.

In the present disclosure, a method for preparing a TOPCon battery substrate includes:
providing a double-sided grooved silicon matrix of a TOPCon battery;
carrying out thermal repair treatment on the silicon matrix;
respectively performing light injection treatment on the front side and the back side of the silicon matrix after thermal repair treatment, thereby obtaining a TOPCon battery substrate.

In present disclosure, firstly, the double-side grooved silicon matrix of TOPCon solar cell is treated by thermal repair, which can greatly increase the overall lattice thermal motion of the silicon substrate; then, light is injected into the front side and the back side in the directions of two different light incidence surfaces, so that both the front side and the back side can absorb light, thereby repairing the defects at the interface between the amorphous silicon and the silicon wafer and improving the quality of the PN junctions. After thermal repair and double-sided light injection, the open circuit voltage after horizontal double-sided electroplating can be improved by 4-10 mV and the photoelectric conversion efficiency can be improved by 0.2-0.8%.

Further, the double-sided grooved silicon matrix of the TOPCon battery is prepared by the following steps:
(a) depositing a passivation film on the surface of a silicon matrix of a TOPCon solar cell to form a coating layer; and
(b) removing the coating layers on the front and back sides of the silicon matrix by using a laser grooving method, to form a grid line pattern on the surfaces of the coating layers.

Further, in step (a), the passivation film is a silicon nitride film.

Further, in step (a), the thickness of the passivation film is 80-100 nm, for example, may be 80 nm, 82 nm, 84 nm, 86 nm, 88 nm, 90 nm, 92 nm, 94 nm, 96 nm, 98 nm, 100 nm, and the like.

Further, in step (b), the laser for laser grooving is an ultraviolet picosecond laser or an ultraviolet nanosecond laser.

Further, in step (b), the laser beam of the laser for laser grooving is a top-hat beam.

In present disclosure, by using the top-hat beam laser for grooving, the spot energy is very uniform, the passivation film in the middle and at the edge can be completely removed, and the damage to the front PN junctions is smaller.

Further, in step (b), the laser peak power in the process of laser grooving is 0.5-2 W, which may be, for example, 0.5 W, 0.6 W, 0.8 W, 1 W, 1.2 W, 1.4 W, 1.6 W, 1.8 W, 2 W, and the like.

Further, in step (b), the grooving width of the finger in the grid line pattern formed after laser grooving is 10-15 μm, which may be, for example, 10 μm, 10.5 μm, 11 μm, 11.5 μm, 12 μm, 12.5 μm, 13 μm, 13.5 μm, 14 μm, 14.5 μm, 15 μm, and the like.

Further, in step (b), the grooving depth in the grid line pattern formed after laser grooving is 80-100 nm, which may be, for example, 80 nm, 82 nm, 84 nm, 86 nm, 88 nm, 90 nm, 92 nm, 94 nm, 96 nm, 98 nm, 100 nm, and the like.

Further, in step (b), the auxiliary gas for laser grooving is any one selected from nitrogen, argon and helium, preferably nitrogen and/or argon.

Further, the thermal repair treatment specifically includes the following steps.

The double-sided grooved silicon matrix of TOPCon solar cell was placed with the front side upward in the atmosphere of protective gas for thermal repair treatment.

Further, the protective gas is nitrogen.

Further, the flow rate of nitrogen is 20-30 L/min, for example, which may be, 20 L/min, 21 L/min, 22 L/min, 23 L/min, 24 L/min, 25 L/min, 26 L/min, 27 L/min, 28 L/min and 29 L/min, 30 L/min, and the like.

Further, the temperature of the thermal repair treatment is 600-800° C., for example, which may be, 600° C., 620° C., 640° C., 660° C., 680° C., 700° C., 720° C., 740° C., 760° C., 780° C., 800° C., and the like.

Further, the duration of the thermal repair treatment is 120-180 s, for example, which may be, 120 s, 125 s, 130 s, 135 s, 140 s, 145 s, 150 s, 155 s, 160 s, 165 s, 170 s, 175 s, 180 s, and the like.

Further, the light injection treatment specifically includes the following steps.

Firstly, one side of the silicon matrix after thermal repair treatment is upward, and light injection treatment is carried out in the atmosphere of protective gas; then it is turned over to make the other side upwards, and placed in the atmosphere of protective gas for light injection treatment to render the treated TOPCon solar cell substrate.

In present disclosure, the front-side light injection processing can be performed first, and then the reverse-side light injection processing can be performed by turning over; or the reverse-side light injection treatment is carried out first, and then the front-side light injection treatment is carried out by turning over.

Further, the protective gas is any one of nitrogen, argon and helium, preferably nitrogen.

Further, the flow rate of the protective gas is 10-15 L/min, for example, which may be, 10 L/min, 10.5 L/min, 11 L/min, 11.5 L/min, 12 L/min, 12.5 L/min, 13 L/min, 13.5 L/min, 14 L/min, 14.5 L/min, 15 L/min, and the like.

Further, heating is needed during the light injection treatment.

Further, the heating temperature is 200-300° C., such as 200° C., 210° C., 220° C., 230° C., 240° C., 250° C., 260° C., 270° C., 280° C., 290° C., 300° C., and the like.

Further, the light radiation intensity of the light injection treatment is 10-30 sun, such as 10 sun, 12 sun, 14 sun, 16 sun, 18 sun, 20 sun, 22 sun, 24 sun, 26 sun, 28 sun, 30 sun, and the like.

Further, the duration of the light injection treatment is 60-120 s, such as 60 s, 65 s, 70 s, 75 s, 80 s, 85 s, 90 s, 95 s, 100 s, 105 s, 110 s, 115th, 120 s, and the like.

Further, the light source of the light injection treatment is white light and/or infrared light.

As a preferred technical solution of the present disclosure, the method for improving the open circuit voltage of a double-sided electroplated TOPCon battery specifically includes the following steps.

### S1, Laser Grooving

(a) depositing a silicon nitride passivation film of 80-100 nm on the surface of a silicon matrix of a TOPCon solar cell to render a coating layer; and
(b) sequentially removing the coating layers on the front and back sides of the silicon matrix by a laser grooving method, and forming a grid line pattern on the surface of the coating layer,
wherein the laser of the laser grooving is an ultraviolet picosecond laser or an ultraviolet nanosecond laser; and the laser beam of the laser for laser grooving is a top-hat beam.

### S2, Thermal Repair Treatment

placing the double-sided grooved silicon matrix of TOPCon solar cell with the front side upward in a nitrogen atmosphere for thermal repair treatment,
wherein the flow rate of the nitrogen is 20-30 L/min; the temperature of thermal repair treatment is 600-800° C.; and the duration of thermal repair treatment is 120-180 s.

### S3, Double-Sided Light Injection Treatment

making, firstly, one side of the silicon matrix after high-temperature thermal repair treatment upward, and placing it in a nitrogen atmosphere for light injection treatment; then, turning it over to make the other side upwards, and placing it in the atmosphere of nitrogen for light injection treatment, supplemented with heating to realize passivation, so as to render the treated TOPCon solar cell substrate,
wherein the flow rate of nitrogen is 10-15 L/min; the heating temperature is 200-300° C.;
the light radiation intensity of light injection treatment is 10-30 sun; the duration of light injection treatment is 60-120 s.

In the second aspect, the present disclosure provides a TOPCon solar cell substrate, which is rendered by the method as described above of improving the open circuit voltage of the double-sided electroplated TOPCon cell.

In a third aspect, the present disclosure provides a double-sided electroplated TOPCon battery, which is rendered by double-sided electroplating for the TOPCon solar cell substrate.

Further, the double-sided electroplating treatment includes any one or a combination of at least two of nickel electroplating, copper electroplating and tin electroplating, preferably a combination of nickel electroplating, copper electroplating and tin electroplating.

Further, the horizontal double-sided electroplating is to sequentially electroplate three metals, namely nickel, copper and tin, on the front and back sides of the battery sheet after light injection to render a double-sided electroplated TOPCon battery.

Embodiments of the present disclosure will be described in detail below with reference to examples, but those skilled in the art will understand that the following examples are only used to illustrate the present disclosure and should not be regarded as limiting the scope of the present disclosure. Where specific conditions are not specified in the examples, it shall be carried out according to the conventional conditions or the conditions suggested by the manufacturer.

To facilitate a clearer understanding of the contents of the present disclosure, specific examples are now described in detail as follows. However, these examples are only exemplary and do not constitute any limitation on the scope of the present disclosure.

### Example 1

This example provided a method for improving the open circuit voltage of a double-sided electroplated TOPCon battery, which specifically included the following steps.

### S1, Laser Grooving

(a) A 90 nm silicon nitride passivation film was deposited on the surface of a silicon matrix of a TOPCon solar cell to render a coating layer.
(b) The coating layers on the front and back sides of the silicon matrix were sequentially removed by a laser grooving method, and a grid line pattern on the surface of the coating layer was formed.

The laser of the laser grooving was an ultraviolet picosecond laser; the laser beam of the laser for laser grooving was a top-hat beam; and the laser peak power in the laser grooving process was 1 W.

The grooving width of the finger in the grid line pattern formed after laser grooving was 12 μm; and the grooving depth was 90 nm.

The auxiliary gas of the laser grooving was nitrogen.

### S2, High-Temperature Thermal Repair Treatment

The double-sided grooved silicon matrix of TOPCon solar cell was placed with the front side upward in a nitrogen atmosphere for high-temperature thermal repair treatment.

The flow rate of the nitrogen gas was 25 L/min; the temperature of high-temperature thermal repair treatment was 700° C.; and the duration of high-temperature thermal repair treatment was 150 s.

### S3, Double-Sided Light Injection Treatment

Firstly, the back side of the silicon matrix after high-temperature thermal repair treatment was upward, and placed in a nitrogen atmosphere for light injection treatment; then it was turned over to make the front side upwards, and placed in nitrogen atmosphere for light injection treatment, supplemented by heating to realize passivation, such that the treated TOPCon solar cell substrate was obtained.

The flow rate of nitrogen was 12 L/min; the heating temperature was 250° C.; the light radiation intensity of light injection treatment was 20 sun; the duration of light injection treatment was 90 s; and the light source of the light injection treatment was white light.

### Example 2

This example provided a method for improving the open circuit voltage of a double-sided electroplated TOPCon battery, which specifically included the following steps.

### S1, Laser Grooving

(a) An 80 nm silicon nitride passivation film was deposited on the surface of a silicon matrix of a TOPCon solar cell to render a coating layer.
(b) The coating layers on the front and back sides of the silicon matrix were sequentially removed by a laser grooving method, and a grid line pattern on the surface of the coating layer was formed.

The laser of the laser grooving was an ultraviolet picosecond laser; the laser beam of the laser for laser grooving was a top-hat beam; the laser peak power in the laser grooving process was 0.5 W.

The grooving width of the finger in the grid line pattern formed after laser grooving was 10 μm; and the grooving depth was 80 nm.

The auxiliary gas of the laser grooving was argon.

### S2, High-Temperature Thermal Repair Treatment

The double-sided grooved silicon matrix of TOPCon solar cell was placed with the front side upward in a nitrogen atmosphere for high-temperature thermal repair treatment.

The flow rate of the nitrogen gas was 20 L/min; the temperature of high-temperature thermal repair treatment was 600° C.; and the duration of high-temperature thermal repair treatment was 180 s.

### S3, Double-Sided Light Injection Treatment

Firstly, the back side of the silicon matrix after high-temperature thermal repair treatment was upward, and placed in a nitrogen atmosphere for light injection treatment; then it was turned over to make the front side upwards, and placed in nitrogen atmosphere for light injection treatment, supplemented by heating to realize passivation, such that the treated TOPCon solar cell substrate was obtained.

The flow rate of nitrogen was 10 L/min; the heating temperature was 300° C.; the light radiation intensity of light injection treatment was 10 sun; the duration of light injection treatment was 120 s; and the light source of the light injection treatment was infrared light.

### Example 3

This example provided a method for improving the open circuit voltage of a double-sided electroplated TOPCon battery, which specifically included the following steps.

### S1, Laser Grooving

(a) A 100 nm silicon nitride passivation film was deposited on the surface of a silicon matrix of a TOPCon solar cell to render a coating layer.
(b) The coating layers on the front and back sides of the silicon matrix were sequentially removed by a laser grooving method, and a grid line pattern on the surface of the coating layer was formed.

The laser of the laser grooving was an ultraviolet nanosecond laser; the laser beam of the laser for laser grooving was a top-hat beam; and the laser peak power in the laser grooving process was 2 W.

The grooving width of the finger in the grid line pattern formed after laser grooving was 15 μm; and the grooving depth was 100 nm.

The auxiliary gas of the laser grooving was nitrogen.

### S2, High-Temperature Thermal Repair Treatment

The double-sided grooved silicon matrix of TOPCon solar cell was placed with the front side upwards in a nitrogen atmosphere for high-temperature thermal repair treatment.

The flow rate of the nitrogen gas was 30 L/min; the temperature of high-temperature thermal repair treatment was 800° C.; and the duration of high-temperature thermal repair treatment was 120 s.

### S3, Double-Sided Light Injection Treatment

Firstly, the back side of the silicon matrix after high-temperature thermal repair treatment was upward, and placed in a nitrogen atmosphere for light injection treatment; then it was turned over to make the front side upwards, and placed in nitrogen atmosphere for light injection treatment, supplemented by heating to realize passivation, such that the treated TOPCon solar cell substrate was obtained.

The flow rate of nitrogen was 15 L/min; the heating temperature was 200° C.; the light radiation intensity of light injection treatment was 30 sun; the duration of light injection treatment was 60 s; and the light source of the light injection treatment was white light.

### Example 4

This example provided a method for increasing the open circuit voltage of a double-sided electroplated TOPCon battery, differed from Example 1 only in that the laser beam of the laser for laser grooving was Gaussian beam, and other steps were exactly the same as Example 1.

### Example 5

This example provided a method for increasing the open circuit voltage of a double-sided electroplated TOPCon battery, differed from Example 1 only in that the laser peak power in the laser grooving process was 0.1 W, and other steps were exactly the same as Example 1.

### Example 6

This example provided a method for increasing the open circuit voltage of a double-sided electroplated TOPCon battery, differed from Example 1 only in that the laser peak power in the laser grooving process was 2.5 W, and other steps were exactly the same as Example 1.

### Example 7

This example provided a method for increasing the open circuit voltage of a double-sided electroplated TOPCon battery, differed from Example 1 only in that the double-sided grooved silicon matrix of TOPCon solar cell was placed with the front side upward in the atmosphere of protective gas for high-temperature thermal repair treatment; then it was turned over to make the other side upwards, and placed in the atmosphere of protective gas for high-temperature thermal repair treatment; and other steps were exactly the same as Example 1.

### Example 8

This example provided a method for increasing the open circuit voltage of a double-sided electroplated TOPCon battery, differed from Example 1 only in that the temperature of the high-temperature thermal repair treatment was 580° C., the duration of the high-temperature thermal repair treatment was 200 s, and other steps were exactly the same as Example 1.

### Example 9

This example provided a method for increasing the open circuit voltage of a double-sided electroplated TOPCon battery, differed from Example 1 only in that the temperature of the high-temperature thermal repair treatment was 820° C., the duration of the high-temperature thermal repair treatment was 100 s, and other steps were exactly the same as Example 1.

### Example 10

This example provided a method for increasing the open circuit voltage of a double-sided electroplated TOPCon battery, differed from Example 1 only in that no heating treatment was carried out during the light injection treatment, and other steps were exactly the same as Example 1.

### Example 11

This example provided a method for increasing the open circuit voltage of a double-sided electroplated TOPCon battery, differed from Example 1 only in that the light radiation intensity of light injection treatment was 5 sun; the duration of light injection treatment was 150 s; and other steps were exactly the same as Example 1.

### Example 12

This example provided a method for increasing the open circuit voltage of a double-sided electroplated TOPCon battery, differed from Example 1 only in that the light radiation intensity of light injection treatment was 35 sun; the duration of light injection treatment was 50 s; and other steps were exactly the same as Example 1

### Comparative Example 1

This Comparative Example provided a TOPCon solar cell substrate, which was prepared by the following method.

(a) A 90 nm silicon nitride passivation film was deposited on the surface of a silicon matrix of a TOPCon solar cell to render a coating layer.

(b) The coating layers on the front and back sides of the silicon matrix were sequentially removed by a laser grooving method, and a grid line pattern on the surface of the coating layer was formed.

The laser of the laser grooving was an ultraviolet picosecond laser; the laser beam of the laser for laser grooving was a top-hat beam; and the laser peak power in the laser grooving process was 1 W.

The grooving width of the finger in the grid line pattern formed after laser grooving was 12 μm; and the grooving depth was 90 nm.

The auxiliary gas of the laser grooving was nitrogen.

### Comparative Example 2

This Comparative Example provided a method for improving the open circuit voltage of a double-sided electroplated TOPCon battery, which specifically included the following steps.

### S1, Laser Grooving

(a) A 90 nm silicon nitride passivation film was deposited on the surface of a silicon matrix of a TOPCon solar cell to render a coating layer.
(b) The coating layers on the front and back sides of the silicon matrix were sequentially removed by a laser grooving method, and a grid line pattern on the surface of the coating layer was formed.

The laser of the laser grooving was an ultraviolet picosecond laser; the laser beam of the laser for laser grooving was a top-hat beam; and the laser peak power in the laser grooving process was 1 W.

The grooving width of the finger in the grid line pattern formed after laser grooving was 12 μm; and the grooving depth was 90 nm.

The auxiliary gas of the laser grooving was nitrogen.

### S2, Double-Sided Light Injection Treatment

Firstly, the back side of the silicon matrix after grooved was upward, and placed in a nitrogen atmosphere for light injection treatment; then it was turned over to make the front side upward, and placed in nitrogen atmosphere for light injection treatment, supplemented by heating to realize passivation, such that the treated TOPCon solar cell substrate was obtained.

The flow rate of nitrogen was 12 L/min; the heating temperature was 250° C.; the light radiation intensity of light injection treatment was 20 sun; the duration of light injection treatment was 90 s; and the light source of the light injection treatment was white light.

### Comparative Example 3

This Comparative Example provided a method for increasing the open circuit voltage of a double-sided electroplated TOPCon battery, which specifically included the following steps.

### S1, Laser Grooving

(a) A 90 nm silicon nitride passivation film was deposited on the surface of a silicon matrix of a TOPCon solar cell to render a coating layer.
(b) The coating layers on the front and back sides of the silicon matrix were sequentially removed by a laser grooving method, and a grid line pattern on the surface of the coating layer was formed.

The laser of the laser grooving was an ultraviolet picosecond laser; the laser beam of the laser for laser grooving was a top-hat beam; and the laser peak power in the laser grooving process was 1 W.

The grooving width of the finger in the grid line pattern formed after laser grooving was 12 μm; and the grooving depth was 90 nm.

The auxiliary gas of the laser grooving was nitrogen.

### S2, High-Temperature Thermal Repair Treatment

The double-sided grooved silicon matrix of TOPCon solar cell was placed with the front side upwards in a nitrogen atmosphere for high-temperature thermal repair treatment to render the treated TOPCon solar cell substrate.

The flow rate of the nitrogen gas was 25 L/min; the temperature of high-temperature thermal repair treatment was 700° C.; and the duration of high-temperature thermal repair treatment was 150 s.

### Comparative Example 4

This Comparative Example provided a method for increasing the open circuit voltage of a double-sided electroplated TOPCon battery, differed from Example 1 only in that only one side was subjected to light injection treatment, specifically: only the back side of the silicon matrix after high-temperature thermal repair treatment was upward, and the light injection treatment was performed in a nitrogen atmosphere; and heating was assisted to realize passivation, such that the treated TOPCon solar cell substrate was obtained.

### Comparative Example 5

This Comparative Example provided a method for increasing the open circuit voltage of a double-sided electroplated TOPCon battery, differed from Example 1 only in that only one side was subjected to light injection treatment, specifically: only the front side of the silicon matrix after high-temperature thermal repair treatment was upward, and the light injection treatment was performed in a nitrogen atmosphere; and heating was assisted to realize passivation, such that the treated TOPCon solar cell substrate was obtained.

### Test Example

### Electrical Performance Test

Test samples: battery substrates treated by methods in Examples 1 to 12 and battery substrates treated by methods in Comparative Examples 1 to 5.

Test method:

(1) Preparation of double-sided electroplated TOPCon battery:

Nickel, copper and tin were electroplated on the front and back sides of the above battery samples in sequence to render a double-sided electroplated TOPCon battery.

The thickness of nickel layer was 1.0 μm; the thickness of copper layer was 9 μm; and the thickness of tin layer was 1.2 μm.

(2) Test data:

Electrical performance (mainly photoelectric conversion efficiency and open circuit voltage): The battery (with a size of 210 mm) rendered in Example 1 was tested by IV test (test condition: 25° C., AM1.5G).

The specific test results were shown in Table 1 below:

TABLE 1

| SAMPLES | Eta(%) | Uoc(V) | Isc(A) | FF(%) | Rs(Ω) |
|---|---|---|---|---|---|
| Example 1 | 23.56 | 0.6985 | 18.24 | 82.78 | 0.00058 |
| Example 2 | 23.58 | 0.6986 | 18.28 | 82.84 | 0.00055 |
| Example 3 | 23.66 | 0.6998 | 18.38 | 83.31 | 0.00052 |
| Example 4 | 23.38 | 0.6955 | 18.13 | 82.67 | 0.00034 |
| Example 5 | 5.11 | 0.5564 | 16.41 | 22.91 | 0.02146 |
| Example 6 | 21.61 | 0.6762 | 17.41 | 81.18 | 0.00127 |
| Example 7 | 23.55 | 0.6983 | 18.27 | 82.81 | 0.00048 |
| Example 8 | 23.38 | 0.6968 | 18.12 | 82.25 | 0.00052 |
| Example 9 | 23.32 | 0.6971 | 18.18 | 82.34 | 0.00063 |
| Example 10 | 23.21 | 0.6942 | 17.98 | 81.34 | 0.00056 |
| Example 11 | 23.48 | 0.6972 | 18.19 | 82.48 | 0.00047 |
| Example 12 | 23.51 | 0.6975 | 18.22 | 82.55 | 0.00056 |
| Comparative | 22.92 | 0.6895 | 17.56 | 82.32 | 0.00071 |
| Example 1 | | | | | |
| Comparative | 23.22 | 0.6945 | 18.05 | 81.76 | 0.00043 |
| Example 2 | | | | | |
| Comparative | 23.10 | 0.6931 | 17.92 | 82.23 | 0.00049 |
| Example 3 | | | | | |
| Comparative | 23.18 | 0.6941 | 18.01 | 82.17 | 0.00041 |
| Example 4 | | | | | |
| Comparative | 23.45 | 0.6975 | 18.34 | 82.56 | 0.00053 |
| Example 5 | | | | | |

According to the test data in Table 1, it can be seen that the open circuit voltage of the double-sided electroplated TOPCon battery prepared by double-sided electroplating for the battery substrate treated by the method disclosed in present disclosure can be improved by 4-10 mV, and the photoelectric conversion efficiency can be improved by 0.2-0.8%. From the comparison between Example 1 and Comparative Examples 1-5, it can be seen that the high-temperature thermal repair disclosed in present disclosure can greatly increase the overall lattice thermal motion of the silicon substrate, and light is injected into the front side and the back side in the directions of two different light incidence surfaces, so that both the front side and the back side can absorb light, thereby the defects at the interface between the amorphous silicon and the silicon wafer are repaired and the quality of the PN junctions is improved.

From the comparison between Example 1 and Examples 5-6, it can be seen that the laser power of 0.1 W is small, which leads to the failure to open the passivation film, so the electroplated metal was difficult to be plated and the efficiency was poor, while the laser power of 2.5 W is too large, the open circuit voltage loss reaches more than 30 mV.

From the comparison between Example 1 and Examples 8-9, it can be seen that the temperature of high-temperature thermal repair treatment is preferably 600-800° C. and the duration is preferably 120-180 s; otherwise, even if the time is prolonged while lowering the temperature, or the temperature is elevated while shortening the processing time, the open circuit voltage and efficiency will be reduced.

From the comparison between Example 1 and Example 10, it can be seen that heating treatment is needed in the process of light injection treatment, otherwise, if there is no heating temperature, only illumination is useless for improving the open circuit voltage.

From the comparison between Example 1 and Examples 11-12, it can be seen that the light radiation intensity of light injection treatment is 10-30 sun, and the duration is 60-120 s, which is helpful to further improve the efficiency in such ranges. Otherwise, even if the time is prolonged while reducing the light radiation intensity, or the light radiation intensity is elevated while shortening processing time, the efficiency of the battery will be reduced.

From the comparison between Example 1 and Comparative Examples 1-4, it can be seen that the collaborative mode of high-temperature thermal repair and double-sided light injection is adopted in present disclosure, which can better repair the defects at the interface between amorphous silicon and silicon wafer and improve the quality of PN junctions, thus the open circuit voltage and efficiency of the prepared battery are improved significantly.

Compared with the prior art, the present disclosure has the following beneficial effects.

(1) In present disclosure, the top-hat beam laser is used to groove, the spot energy is very uniform, the passivation film in the middle and at the edge can be completely removed, and the damage to the front PN junctions is smaller.

(2) In present disclosure, the high-temperature thermal repair can greatly increase the overall lattice thermal motion of the silicon substrate; and light is injected into the front side and the back side in the directions of two different light incidence surfaces, which makes both the front side and the back side absorb light, thereby repairing the defects at the interface between the amorphous silicon and the silicon wafer and improving the quality of the PN junctions.

(3) In present disclosure, after high-temperature thermal repair and double-sided light injection are carried out on the double-sided grooved semi-finished products, the open circuit voltage can be increased by 4-10 mV and the photoelectric conversion efficiency can be improved by 0.2-0.8% after horizontal double-sided electroplating.

The present disclosure also provides the following items.

1. The method for improving the open circuit voltage of a double-sided electroplated TOPCon battery, wherein the method includes the following steps:
performing firstly the thermal repair treatment on the double-sided grooved silicon matrix of TOPCon solar cell, and then performing light injection treatment on the front side and back side of the silicon matrix after thermal repair treatment respectively to render the treated TOPCon solar cell substrate.

2. The method of item 1, wherein the double-sided grooved silicon matrix of TOPCon solar cell is prepared by the following steps:
(a) depositing a passivation film on the surface of a silicon matrix of a TOPCon solar cell to render a coating layer; and
(b) removing the coating layers on the front side and back side of the silicon matrix by using a laser grooving method, and forming a grid line pattern on the surface of the coating layer.

3. The method of item 2, wherein in step (a), the passivation film is a silicon nitride film; preferably, in step (a), the thickness of the passivation film is 80-100 nm.

4. The method of item 2 or 3, wherein in step (b), the laser for laser grooving is an ultraviolet picosecond laser or an ultraviolet nanosecond laser;
preferably, in step (b), the laser beam of the laser for laser grooving is a top-hat beam;
preferably, in step (b), the laser peak power is 0.5-2 W in the process of laser grooving;
preferably, in step (b), the grooving width of the finger in the grid line pattern formed after laser grooving is 10-15 μm;
preferably, in step (b), the grooving depth in the grid line pattern formed after laser grooving is 80-100 nm; and
preferably, in step (b), the auxiliary gas for laser grooving is any one selected from nitrogen, argon and helium, and preferably nitrogen and/or argon.

5. The method of item 1, wherein the thermal repair treatment specifically includes the following steps:
placing the double-sided grooved silicon matrix of TOPCon solar cell with the front side upward in the atmosphere of protective gas for thermal repair treatment.

6. The method of item 5, wherein the protective gas is any one of nitrogen, argon and helium, preferably nitrogen, preferably, the flow rate of the protective gas is 20-30 L/min;
preferably, the temperature of the thermal repair treatment is 600-800° C.; and
preferably, the duration of the thermal repair treatment is 120-180 s.

7. The method of item 1, wherein the light injection treatment specifically includes the following steps:
making, firstly, one side of the silicon matrix after thermal repair treatment upward, and performing light injection treatment in the atmosphere of protective gas; then turning it over to make the other side upwards, and placing it in the atmosphere of protective gas for light injection treatment to render the treated TOPCon solar cell substrate.

8. The method of item 7, wherein the protective gas is nitrogen;
preferably, the flow rate of the nitrogen is 10-15 L/min;
preferably, heating is required during the light injection treatment;
preferably, the heating temperature is 200-300° C.;
preferably, the light radiation intensity of the light injection treatment is 10-30 sun;
preferably, the duration of the light injection treatment is 60-120 s; and
preferably, the light source of the light injection process is white light and/or infrared light.

9. A TOPCon solar cell substrate, wherein the TOPCon solar cell substrate is rendered by the method described in any one of items 1-8.

10. A double-sided electroplated TOPCon battery, wherein the double-sided electroplated TOPCon battery is rendered by double-sided electroplating for the TOPCon solar cell substrate as described in item 9; and

preferably, the double-sided electroplating treatment includes any one or a combination of at least two of nickel electroplating, copper electroplating and tin electroplating, and preferably, the combination of nickel electroplating, copper electroplating and tin electroplating.

Although the present disclosure has been illustrated and described with specific examples, it should be realized that many other changes and modifications can be made without departing from the spirit and scope of the present disclosure. Therefore, it means that all such changes and modifications falling within the scope of the present disclosure are included in the appended claims.

What is claimed is:

1. A method for preparing a TOPCon battery substrate, comprising:
providing a double-sided grooved silicon matrix of a TOPCon battery;
carrying out a thermal repair treatment on the double-sided grooved silicon matrix of the TOPCon battery; and
performing a light injection treatment on a front side and a back side of the double-sided grooved silicon matrix of the TOPCon battery after the thermal repair treatment, respectively, wherein the TOPCon battery substrate is obtained.

2. The method according to claim 1, wherein the double-sided grooved silicon matrix of the TOPCon solar cell is prepared by the following steps:
a) depositing a passivation film on a surface of a silicon matrix of a TOPCon solar cell to form a coating layer; and
b) removing the coating layers on a front side and a back side of the silicon matrix by using a laser grooving method, and forming a grid line pattern on a surface of the coating layer.

3. The method according to claim 2, wherein in the step a), the passivation film is a silicon nitride film, wherein a thickness of the passivation film is 80-100 nm.

4. The method according to claim 2, wherein in the step b), a laser for laser grooving is an ultraviolet picosecond laser or an ultraviolet nanosecond laser.

5. The method according to claim 4, wherein in the step b), a laser beam of the laser for the laser grooving is a top-hat beam, wherein
laser peak power is 0.5-2 W in a process of the laser grooving.

6. The method according to claim 4, wherein in the step b), a grooving width of a finger in the grid line pattern formed after the laser grooving is 10-15 μm; and a grooving depth in the grid line pattern formed after the laser grooving is 80-100 nm.

7. The method according to claim 4, wherein in the step b), an auxiliary gas for the laser grooving is one selected from nitrogen, argon, and helium.

8. The method according to claim 1, wherein the thermal repair treatment comprises the following steps:
placing the double-sided grooved silicon matrix of the TOPCon solar cell with the front side upward in an atmosphere of protective gas for the thermal repair treatment.

9. The method according to claim 8, wherein the protective gas is one of nitrogen, argon, and helium.

10. The method according to claim 8, wherein a flow rate of the protective gas is 20-30 L/min.

11. The method according to claim 8, wherein a temperature of the thermal repair treatment is 600-800° C.; and a duration of the thermal repair treatment is 120-180 s.

12. The method according to claim 1, wherein the light injection treatment comprises the following steps:
making a first side of the double-sided grooved silicon matrix of the TOPCon battery after the thermal repair treatment upwards, and placing the double-sided grooved silicon matrix of the TOPCon battery after the thermal repair treatment in an atmosphere of protective gas for the light injection treatment to obtain a resulting product; turning the resulting product over to make a second side upwards, and placing the resulting product in the atmosphere of the protective gas for the light injection treatment, to render a treated TOPCon solar cell substrate.

13. The method according to claim 12, wherein the protective gas is nitrogen.

14. The method according to claim 13, wherein a flow rate of the nitrogen is 10-15 L/min.

15. The method according to claim 12, wherein heating is needed during the light injection treatment; and a heating temperature is 200-300° C.

16. The method according to claim 12, wherein a light radiation intensity of the light injection treatment is 10-30 sun; a duration of the light injection treatment is 60-120 s; and a light source of the light injection treatment is white light and/or infrared light.

17. A TOPCon battery substrate, wherein the TOPCon battery substrate is prepared by the method according to claim 1.

18. A double-sided electroplated TOPCon battery, wherein the double-sided electroplated TOPCon battery is obtained by a double-sided electroplating treatment for the TOPCon battery substrate according to claim 17.

19. The double-sided electroplated TOPCon battery according to claim 18, wherein the double-sided electroplating treatment comprises one or a combination of at least two of nickel electroplating, copper electroplating, and tin electroplating.

20. The double-sided electroplated TOPCon battery according to claim 19, wherein the double-sided electroplating treatment is a combination of the nickel electroplating, the copper electroplating, and the tin electroplating.
